(19) United States
(12) Patent Application Publication
(10) Pub. No.: US 2016/0099283 A1
(43) Pub. Date: Apr. 7, 2016

(54) PHOTOSENSOR WITH CHANNEL REGION HAVING CENTER CONTACT

(71) Applicant: OMNIVISION TECHNOLOGIES, INC., Santa Clara, CA (US)

(72) Inventor: Nail I. Khaliullin, Sunnyvale, CA (US)

(21) Appl. No.: 14/506,399

(22) Filed: Oct. 3, 2014

(51) Int. Cl. H01L 27/146

(52) U.S. Cl. CPC H01L 27/14679; H01L 27/14612; H01L 27/14636; H01L 27/1461

(57) ABSTRACT

A pixel cell includes a charge accumulation region having a second doping polarity buried completely in a semiconductor substrate having a first doping polarity beneath a first surface. The charge accumulation region accumulates image charge in response to light directed through a second surface. A channel region is disposed in the semiconductor substrate between the first surface and the charge accumulation region. A variable resistance of the channel region is responsive to the image charge accumulated in the charge accumulation region. A center contact coupled to a central portion of the channel region through the first surface to provide a radial current path through the channel region between the central portion of the channel region and a periphery of the channel region around the charge accumulation region to the semiconductor substrate. A readout signal responsive to the image charge in the charge accumulation region is provided at the center contact.

### BACKGROUND INFORMATION

1. Field of the Disclosure

The present invention is generally related to semiconductor devices, and more specifically, the present invention is directed to image sensors implemented in semiconductor devices.

2. Background

Image sensors have become ubiquitous. They are widely used in digital cameras, cellular phones, security cameras, as well as, medical, automobile, and many other applications. The technology used to manufacture image sensors, and in particular, complementary metal-oxide-semiconductor (CMOS) image sensors (CIS), has continued to advance at a great pace. For example, the demands for higher resolution and lower power consumption have encouraged the further miniaturization and integration of these image sensors.

Typical CMOS image sensor pixel cells are implemented using either three transistor (3T) or four transistor (4T) designs. For instance, a 4T pixel cell design generally includes a transfer transistor to transfer image charge into a floating diffusion, a transistor to amplify a signal on the floating diffusion to an output signal, a transistor to reset the charge in the floating diffusion, and a transistor to select the pixel for readout. A challenge presented with a pixel cell having the transfer transistor is that dark current may be generated under the gate of the transfer transistor during the transfer of charge into the floating diffusion. In addition, some charge may be left behind when transferring charge into the floating diffusion, which can increase image lag and decrease image quality. Furthermore, the inclusion of the additional transfer transistor occupies valuable chip real estate and decreases the fill factor of the image sensor.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a diagram illustrating one example of an imaging system including an example image sensor with an example pixel array having pixel cells having a radial channel region with a completely buried depletion region in accordance with the teachings of the present invention.

FIG. 2 is a schematic illustrating one example of pixel cell having a radial channel region with a completely buried depletion region in accordance with the teachings of the present invention.

FIG. 3A is a cross-section view illustrating an example pixel cell having a variable resistance in a radial channel region with a completely buried depletion region in accordance with the teachings of the present invention.

FIG. 3B is a cross-section view illustrating another example pixel cell having a variable resistance in a radial channel region with a completely buried depletion region in accordance with the teachings of the present invention.

FIG. 4 is a top view diagram illustrating one example of a radial channel region of a pixel cell in accordance with the teachings of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment”, “an embodiment”, “one example” or “an example” means that a particular feature, structure or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

As will be discussed, an example image sensor in accordance with the teaching of the present invention eliminates the need for a transfer transistor with a pixel cell structure that includes a semiconductor substrate that features a completely buried charge accumulation region that generates and modulates a completely buried depletion region beneath a surface of the semiconductor substrate in response to incident light. The buried depletion region overlaps with a radial channel region to vary a resistance of the radial channel region, which is used to output a readout signal of the pixel cell in response to the incident light in accordance with the teachings of the present invention. Since no transfer transistor is included in the example pixel cell, the dark current is reduced since there is no longer a transfer transistor gate under which charge is transferred to a floating diffusion. Furthermore, since the depletion region of the example pixel cell is completely buried and does not come into contact with a surface of the semiconductor substrate, dark current originating as a consequence of the depletion region coming into contact with the surface of the semiconductor substrate is further reduced in accordance with the teachings of the present invention

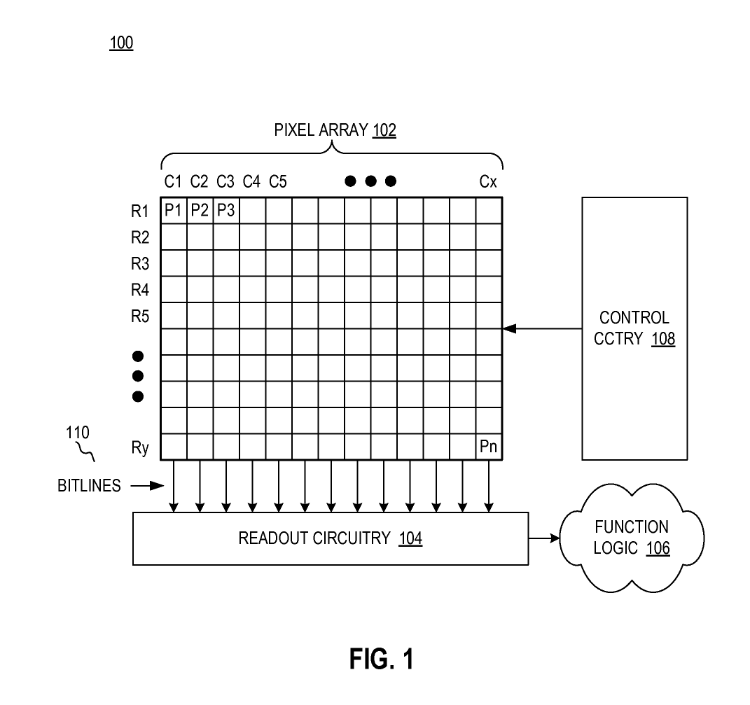

To illustrate, FIG. 1 is a diagram illustrating one example of an imaging system 100 including an example image sensor in accordance with the teachings of the present invention. As shown in the depicted example, imaging system 100 includes a pixel array 102, readout circuitry 104, function logic 106, and control circuitry 108. Pixel array 102 is a two-dimensional (2D) array of imaging sensors or pixel cells (e.g., pixels P1, P2 . . . , Pn). In one example, each pixel cell is a complementary metal-oxide-semiconductor (CMOS) imaging pixel. As illustrated, each pixel cell is arranged into a row (e.g., rows R1 to Ry) and a column (e.g., column C1 to Cx) to acquire image data of a person, place, object, etc., which can then be used to render a 2D image of the person, place, or object, etc. As will discussed in further detail below, in one example, each pixel cell is implemented in a semiconductor substrate without transfer transistors, and with radial channel regions with completely buried depletion regions in accordance with the teachings of the present invention.

In one example, after each pixel cell has accumulated its image data or image charge, the image data is readout by readout circuitry 104 through column bitlines 110 and then transferred to function logic 106. In various examples, readout circuitry 104 may also include additional amplification circuitry, additional analog-to-digital (ADC) conversion circuitry, or otherwise. Function logic 106 may simply store the image data or even manipulate the image data by applying post image effects (e.g., crop, rotate, remove red eye, adjust brightness, adjust contrast, or otherwise). In one example, readout circuitry 104 may readout a row of image data at a time along readout column bitlines 110 (illustrated) or may readout the image data using a variety of other techniques (not illustrated), such as a serial readout or a full parallel readout of all pixel cells simultaneously.

In one example, control circuitry 108 is coupled to pixel array 102 to control operational characteristics of pixel array 102. For example, control circuitry 108 may generate a shutter signal for controlling image acquisition. In one example, the shutter signal is a global shutter signal for simultaneously enabling all pixel cells within pixel array 102 to simultaneously capture their respective image data during a single acquisition window. In another example, the shutter signal is a rolling shutter signal such that each row, column, or group of pixels is sequentially enabled during consecutive acquisition windows.

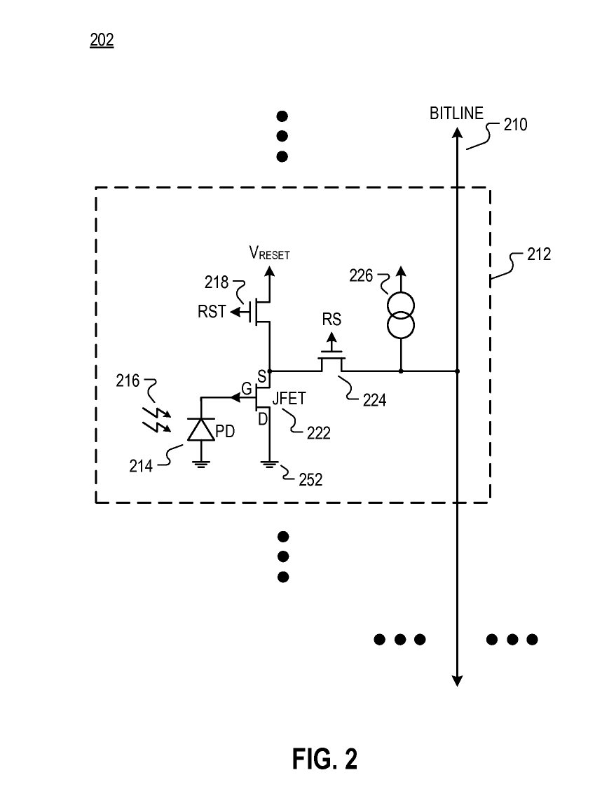

FIG. 2 is a schematic illustrating one example of pixel cell 212 of a pixel array 202 in accordance with the teachings of the present invention. It is appreciated that pixel cell 212 and pixel array of FIG. 2 may be example implementations of one of the pixel cells (e.g., pixels P1, . . . , P2 Pn) and pixel array 102 of FIG. 1, and that similarly named and numbered elements referenced below are coupled and function similar to as described above. As shown in the example depicted in FIG. 2, pixel cell 212 includes a photodiode PD 214 to accumulate image charge, a junction field effect transistor (JFET) 222, a reset transistor 218, a row select transistor 224, and a constant current source 226 coupled to the bitline 210 and row select transistor 224 as shown. As will be discussed, the photodiode PD 214 in combination with the JFET 222 form an active pixel structure in accordance with the teachings of the present invention. During operation, photodiode PD 214 accumulates image charge in response to incident light 216 during an integration time. The accumulated image charge is coupled to the gate of JFET 222 as an input signal. The drain of JFET 222 is coupled to a fixed potential, which in the depicted example is ground terminal 252, such that JFET 222 is coupled in a common drain configuration, or a source follower coupled transistor, with a readout signal therefore output at the source of JFET 222. As will be discussed in further detail below, JFET 222 is implemented with radial channel region with completely buried depletion regions, which reduces dark current generation in accordance with the teachings of the present invention.

As shown in the illustrated example, reset transistor 218 is coupled between a reset voltage VRESET and a source terminal of JFET 222 to reset the pixel cell 212 (e.g., discharge/charge the photodiode PD 214 to the preset voltage VRESET) in response to a reset signal RST prior to integration. Row select transistor 224 selectively couples the output of pixel cell 212 to the readout column bitline 210 in response to a row select signal RS. In one example, the RST signal, and the RS signal, may be generated by control circuitry, such as for example control circuitry 108 discussed above in FIG. 1. It is appreciated that pixel cell 212 is implemented without a transfer transistor, which reduces the overall transistor count and improves fill factor in accordance with the teachings of the present invention.

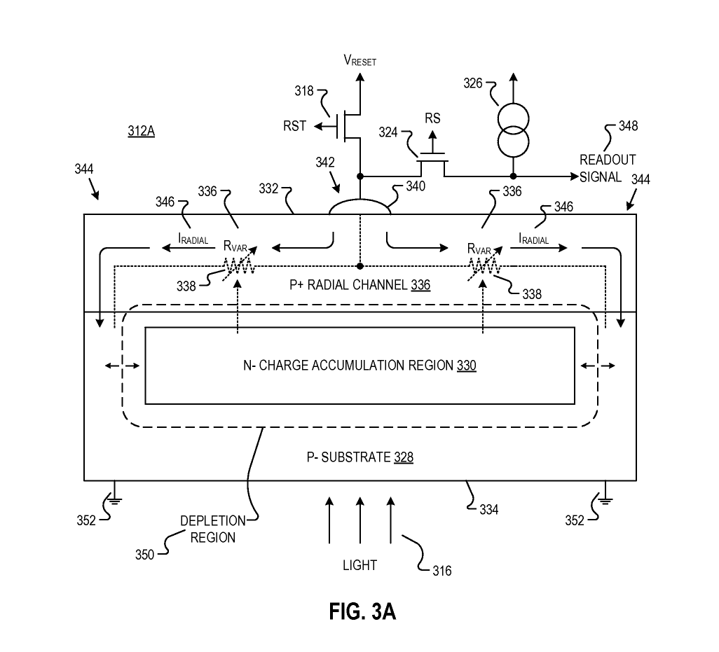

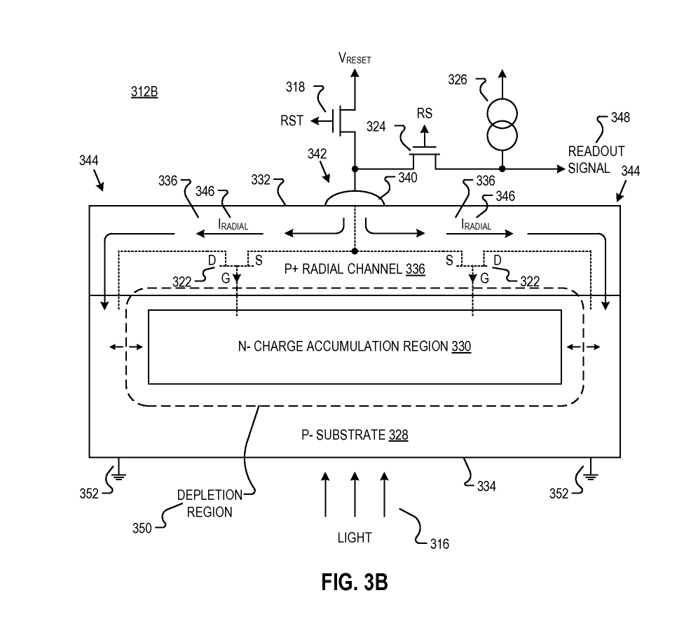

FIG. 3A is a cross-section view illustrating an example pixel cell 312A having a variable resistance in a radial channel region with a completely buried depletion region in accordance with the teachings of the present invention. It is appreciated that pixel cell 312A as shown in FIG. 3A may be an example implementation of one of the pixel cells (e.g., pixels P1, P2 . . . , Pn) of FIG. 1, and/or pixel cell 212 of FIG. 2, and that similarly named and numbered elements referenced below are coupled and function similar to as described above.

As shown in the example depicted in FIG. 3A, pixel cell 312A includes a semiconductor substrate 328 having a first doping polarity. For instance, in the depicted example, semiconductor substrate 328 has a P− doping. A charge accumulation region 330 is buried completely in the semiconductor substrate 328 beneath a first side surface 332 of semiconductor substrate 328. In the illustrated example, the first side surface 332 is a front side surface of semiconductor substrate 328.

In the example, a charge accumulation region 330 is doped with dopants having an opposite polarity of the dopants of semiconductor substrate 328. Therefore, in an example in which semiconductor substrate 328 has P− doping, charge accumulation region 330 has N− doping. Charge accumulation region 330 is coupled to accumulate image charge in response to incident light 316 directed through a second side surface 334, which is an opposite surface with respect to first side surface 332. For instance, in the depicted example, the second side surface 334 is a backside surface of semiconductor substrate 328. The amount of image charge generated in charge accumulation region 330 is a function of the photogenerated current generated in charge accumulation region 330 in response to incident light 316, and the integration time.

In the example, a buried depletion region 350 is generated proximate to the charge accumulation region 330 in response to the image charge that is generated in charge accumulation region 330. The buried depletion region 350 is completely buried beneath the first side surface 332 of semiconductor substrate 328. The size of buried depletion region 350 in semiconductor substrate 328 varies in response to the amount of image charge generated in charge accumulation region 330.

A channel region 336 is disposed in the semiconductor substrate 328 between the first side surface 332 and the charge accumulation region 330. In the example, the channel region 336 is doped with dopants having the same polarity as the dopants of the semiconductor substrate 328, and with a higher doping concentration. Thus, in an example in which semiconductor substrate 328 has P− doping, channel region 336 has P+ doping. As the size of buried depletion region 350 in semiconductor substrate 328 expands, the amount of overlap of buried depletion region 350 with channel region 336 increases. As the size of buried depletion region 350 decreases, the amount of overlap of buried depletion region 350 with channel region 336 decreases.

As illustrated in the depicted example, a center contact 340 is coupled to a central portion 342 of the channel region 336 through the first side surface 332. As such, a current path is provided for a radial current I_{RADIAL} 346 through the channel region 336 between the central portion 342 of the channel region 336 and an outer periphery 344 of the channel region 336 around the charge accumulation region 330 to the semiconductor substrate 328 as shown. The resistance of the radial current path through the channel region 336 is varied in response to the amount of overlap of the buried depletion region 350 in response to the amount of image charge in charge accumulation region 330 in accordance with the teachings of the present invention. This variable resistance of the radial current path through the channel region 336 is represented in FIG. 3A as variable resistance R_{VAR} 338 between the central portion 342 of the channel region 336 and an outer periphery 344 of the channel region 336.

In the example, as the amount of overlap of buried depletion region 350 with channel region 336 increases, the resistance of variable resistance R_{VAR} 338 increases until the overlap of buried depletion region 350 with channel region 336 completely “pinches-off” the channel region 336, at which point channel region 336 is depleted of charge carriers and conductance in channel region 336 is therefore very low. Accordingly, the variable resistance R_{VAR} 338 is very high and the radial current I_{RADIAL} 346 drops to substantially zero. It is appreciated that the channel region 336 may be “pinched-off” completely by buried depletion region 350 without buried depletion region 350 ever reaching first side surface 332, which can reduce dark current in accordance with the teachings of the present invention. As the amount of overlap of buried depletion region 350 with channel region 336 decreases, the resistance of variable resistance R_{VAR} 338 decreases accordingly.

In one example, the amount of overlap of buried depletion region 350 with channel region 336 is a function of the amount of image charge in charge accumulation region 330. Correspondingly, the magnitude of the radial current I_{RADIAL} 346 is a function of the amount of image charge in charge accumulation region 330 in accordance with the teachings of the present invention. Thus, as the amount of image charge in charge accumulation region 330 increases, the radial current I_{RADIAL} 346 increases. As the amount of image charge in charge accumulation region 330 decreases, the radial current I_{RADIAL} 346 decreases until the channel region 336 is “pinched-off” completely, at which point the radial current I_{RADIAL} 346 drops to substantially zero.

With the variable resistance R_{VAR} 338 and radial current I_{RADIAL} 346 responsive to the image charge in charge accumulation region 330 as described above, a readout signal 348 responsive to the image charge accumulated in the charge accumulation region 330 is coupled to be provided at the center contact 340 through a row select transistor 324 in accordance with the teachings of the present invention. In one example, row select transistor 324 is coupled between a bitline output of the pixel cell (e.g., bitline 210 of FIG. 2) and the center contact 340. As shown in the example of FIG. 3A, the row select transistor 324 is coupled to output the readout signal 348 from the center contact 340 to the bitline output in response to a row select signal RS coupled to the row select transistor 324. In one example, a constant current source 326 may be coupled to the output of the pixel cell 312A at row select transistor 324 as shown.

The example depicted in FIG. 3A also shows that a reset transistor 318 is coupled between the center contact 340 and a reset voltage VRESET. In operation, the reset transistor 318 is coupled to reset the image charge accumulated in the accumulation region 330 in response to a reset signal RST coupled to the reset transistor 318. For instance, the reset signal RST may be used to reset pixel cell 312A before integration of light 316. As such, reset transistor 318 is switched on during a reset operation, which couples center contact 340 to the reset voltage V_{RESET}, and pulls out substantially all accumulated image charge in charge accumulation region 330 through center contact 340 in accordance with the teachings of the present invention. At this point, charge accumulation region 330 is completely depleted of image charge, which expands buried depletion region 350 to “pinch-off” channel region 336, which depletes channel region 336 of charge carriers, and increases the resistance of variable resistance R_{VAR} 338 after a reset and before integration in accordance with the teachings of the present invention.

FIG. 3B is a cross-section view illustrating another example of pixel cell 312B having a JFET with a variable resistance in a radial channel region and a completely buried depletion region in accordance with the teachings of the present invention. It is appreciated that pixel cell 312B as shown in FIG. 3B may be an example implementation of one of the pixel cells (e.g., pixels P1, P2 . . . , Pn) of FIG. 1, and/or pixel cell 212 of FIG. 2, and/or pixel cell 312A of FIG. 3A, and that similarly named and numbered elements referenced below are coupled and function similar to as described above. Accordingly, similarly named and numbered elements are not necessarily described again in detail for brevity.

One difference between pixel cell 312B of FIG. 3B and pixel cell 312A of FIG. 3A, is that the variable resistance R_{VAR} 338 of channel region 336 illustrated in FIG. 3A is represented with a JFET 322 in channel region 336 in pixel cell 312B as shown in FIG. 3B. As shown in the example depicted in FIG. 3B, the central portion 342 of the channel region 336 is represented by, or is coupled to, a source terminal of JFET 322, and the outer periphery 344 of the channel region 336 is represented by, or is coupled to, a drain terminal of the JFET 322. Accordingly, it is appreciated that the channel region 336 between the central portion 342 of the channel region 336 and the outer periphery 344 of the channel region 336 is therefore a channel of the JFET 322. As such, a gate of the JFET 322 is responsive, or is coupled to, the charge accumulation region 330 such that a variable resistance of the channel of the JFET 322 is responsive to the image charge accumulated in the accumulation region 330 in accordance with the teachings of the present invention. As shown in the example depicted in FIG. 3B, semiconductor substrate is coupled to a fixed potential, which in the depicted example is ground terminal 352, such that the drain of JFET 322 is coupled to ground terminal 352 through semiconductor substrate 328. Accordingly, JFET 322 is coupled in a common drain configuration, or is a source follower coupled transistor, with a readout signal 348 output at the source of JFET 322 through center contact 340, and through row select transistor 324 in accordance with the teachings of the present invention.

It is noted that the operation of pixel cell 312B is similar to operation of pixel cell 312A in accordance with the teachings of the present invention. For instance, reset transistor 318 is coupled to reset the image charge in charge accumulation region 330 prior to integration. In addition, the value of the variable resistance in the channel region 336 and/or the channel of JFET 322 is responsive to the amount of image charge in charge accumulation region 330, which varies the amount of overlap of the buried depletion region 350 with the channel region 336 and/or the channel of JFET 322. Accordingly, the readout signal 348 is output by the pixel cell 312B in response to the amount of image charge generated in charge accumulation region 330 in response to incident light 316 in accordance with the teachings of the present invention.

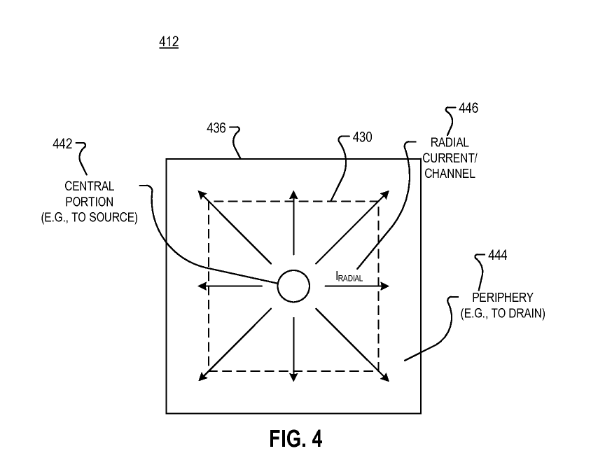

FIG. 4 is a top view diagram illustrating one example of a pixel cell 412 showing the radial current in a radial channel region 436 in accordance with the teachings of the present invention. It is appreciated that pixel cell 412 of FIG. 4 may be an example implementation of one of the pixel cells (e.g., pixels P1, P2 . . . , Pn) of FIG. 1, and/or pixel cell 212 of FIG. 2, and/or pixel cell 312A of FIG. 3A, and/or pixel cell 312B of FIG. 3B, and that similarly named and numbered elements referenced below are coupled and function similar to as described above. As shown, the output periphery 444 of the channel region 436 as shown in FIG. 4 surrounds the central portion 442 of the channel region 436. Accordingly, the channel region 436 through which the radial current I_{RADIAL} 446 flows is a radial channel region with the radial current path disposed in the channel region 436 between the central portion 442 of the channel region 436 and extending outward to the outer periphery 444 of the channel region 436 in accordance with the teachings of the present invention. In one example, the central portion 442 corresponds to, or is coupled to, the source terminal of the JFET (e.g., JFET 322 of FIG. 3B) and the outer periphery 444 corresponds to, or is coupled to, the drain terminal of the JFET (e.g., JFET 322 of FIG. 3B).

The above description of illustrated examples of the present invention, including what is described in the Abstract, are not intended to be exhaustive or to be limitation to the precise forms disclosed. While specific embodiments of, and examples for, the invention are described herein for illustrative purposes, various equivalent modifications are possible without departing from the broader spirit and scope of the present invention.

These modifications can be made to examples of the invention in light of the above detailed description. The terms used in the following claims should not be construed to limit the invention to the specific embodiments disclosed in the specification and the claims. Rather, the scope is to be determined entirely by the following claims, which are to be construed in accordance with established doctrines of claim interpretation. The present specification and figures are accordingly to be regarded as illustrative rather than restrictive.

What is claimed is:

1. A pixel cell, comprising:
a semiconductor substrate having a first doping polarity;
a charge accumulation region having a second doping polarity buried completely in the semiconductor substrate beneath a first side surface of the semiconductor substrate, wherein the second doping polarity is opposite with respect to the first doping polarity, wherein the charge accumulation region is coupled to accumulate image charge in response to light directed through a second side surface of semiconductor substrate, wherein the second side surface is opposite with respect to the first side surface;
a channel region disposed in the semiconductor substrate between the first side surface and the charge accumulation region, wherein a variable resistance of the channel region is responsive to the image charge accumulated in the charge accumulation region; and
a center contact coupled to a central portion of the channel region through the first side surface to provide a radial current path through the channel region between the central portion of the channel region and a periphery of the channel region around the charge accumulation region to the semiconductor substrate, wherein a readout signal responsive to the image charge accumulated in the charge accumulation region is coupled to be provided at the center contact.

2. The pixel cell of claim 1 further comprising a buried depletion region responsive to the image charge, wherein the buried depletion region is generated completely beneath the first side surface and overlaps the channel region proximate to the charge accumulation region to adjust the variable resistance of the channel region in response to the image charge accumulated in the charge accumulation region.

3. The pixel cell of claim 1 wherein the periphery of the channel region surrounds the central portion of the channel region such that the channel region is a radial channel region with the radial current path disposed in the channel region between the central portion of the channel region and the periphery of the channel region.

4. The pixel cell of claim 1 wherein the central portion of the channel region is a first terminal of a junction field effect transistor (JFET), wherein the periphery of the channel region is a second terminal of the JFET, wherein the channel region between the central portion of the channel region and the periphery of the channel region is a channel of the JFET, and wherein a gate of the JFET is coupled to the charge accumulation region such that a variable resistance of the channel of the JFET is responsive to the image charge accumulated in the accumulation region.

5. The pixel cell of claim 4 wherein the first and second terminals of the JFET comprise a source and a drain of the JFET.

6. The pixel cell of claim 5 wherein the drain of the JFET is coupled to a first potential through the semiconductor substrate such that the JFET is a source follower coupled JFET.

7. The pixel cell of claim 1 further comprising a reset transistor coupled between the center contact and a reset voltage, wherein the reset transistor is coupled to reset the image charge accumulated in the accumulation region in response to a reset signal coupled to the reset transistor.

8. The pixel cell of claim 1 further comprising a row select transistor coupled between a bitline output of the pixel cell and the center contact, wherein the row select transistor is coupled to output the readout signal from the center contact to the bitline output in response to a row select signal coupled to the row select transistor.

9. The pixel cell of claim 8 further comprising a constant current source coupled to the bitline output of the pixel cell.

10. The pixel cell of claim 1 wherein the semiconductor substrate has the first doping polarity at a first doping concentration and wherein the channel region has the first doping polarity at a second doping concentration, wherein the second doping concentration is greater than the first doping concentration.

11. The pixel cell of claim 1 wherein the first doping polarity is a p type doping polarity, and wherein the second doping polarity is an n type doping polarity.

12. The pixel cell of claim 1 wherein the first side is a front side of the semiconductor substrate, and wherein the second side is a backside of the semiconductor substrate.

13. An imaging sensor system, comprising:
a pixel array having a plurality of pixel cells disposed in a semiconductor substrate having a first doping polarity, wherein each one of the plurality of pixel cells includes:
a charge accumulation region having a second doping polarity buried completely in the semiconductor substrate beneath a first side surface of the semiconductor substrate, wherein the second doping polarity is opposite with respect to the first doping polarity, wherein the charge accumulation region is coupled to accumulate image charge in response to light directed through a second side surface of semiconductor substrate, wherein the second side surface is opposite with respect to the first side surface;
a channel region disposed in the semiconductor substrate between the first side surface and the charge accumulation region, wherein a variable resistance of the channel region is responsive to the image charge accumulated in the charge accumulation region; and
a center contact coupled to a central portion of the channel region through the first side surface to provide a radial current path through the channel region between the central portion of the channel region and a periphery of the channel region around the charge accumulation region to the semiconductor substrate, wherein a readout signal responsive to the image charge accumulated in the charge accumulation region is coupled to be provided at the center contact;
control circuitry coupled to the pixel array to control operation of the pixel array; and
readout circuitry coupled to the pixel array to readout the readout signal from each one of the plurality of pixel cells.

14. The imaging sensor system of claim 13 further comprising function logic coupled to the readout circuitry to store the readout signal from each one of the plurality of pixel cells.

15. The imaging sensor system of claim 13 wherein each one of the plurality of pixel cells further includes a buried depletion region responsive to the image charge, wherein the buried depletion region is generated completely beneath the first side surface and overlaps the channel region proximate to the charge accumulation region to adjust the variable resistance of the channel region in response to the image charge accumulated in the charge accumulation region.

16. The imaging sensor system of claim 13 wherein the periphery of the channel region surrounds the central portion of the channel region such that the channel region is a radial channel region with the radial current path disposed in the channel region between the central portion of the channel region and the periphery of the channel region.

17. The imaging sensor system of claim 13 wherein the central portion of the channel region is a first terminal of a junction field effect transistor (JFET), wherein the periphery of the channel region is a second terminal of the JFET, wherein the channel region between the central portion of the channel region and the periphery of the channel region is a channel of the JFET, and wherein a gate of the JFET is coupled to the charge accumulation region such that a variable resistance of the channel of the JFET is responsive to the image charge accumulated in the accumulation region.

18. The imaging sensor system of claim 17 wherein the first and second terminals of the JFET comprise a source and a drain of the JFET.

19. The imaging sensor system of claim 18 wherein the drain of the JFET is coupled to a first potential through the semiconductor substrate such that the JFET is a source follower coupled JFET.

20. The imaging sensor system of claim 13 wherein each one of the plurality of pixel cells further includes a reset transistor coupled between the center contact and a reset voltage, wherein the reset transistor is coupled to reset the image charge accumulated in the accumulation region in response to a reset signal coupled to the reset transistor.

21. The imaging sensor system of claim 13 wherein each one of the plurality of pixel cells further includes a row select transistor coupled between a bitline output of the pixel cell and the center contact, wherein the row select transistor is coupled to output the readout signal from the center contact to the bitline output in response to a row select signal coupled to the row select transistor.

22. The imaging sensor system of claim 21 wherein each one of the plurality of pixel cells further includes a constant current source coupled to the bitline output of the pixel cell.

23. The imaging sensor system of claim 13 wherein the semiconductor substrate has the first doping polarity at a first doping concentration and wherein the channel region of each one of the plurality of pixel cells has the first doping polarity at a second doping concentration, wherein the second doping concentration is greater than the first doping concentration.

24. The imaging sensor system of claim 13 wherein the first doping polarity is a p type doping polarity, and wherein the second doping polarity is an n type doping polarity.

25. The imaging sensor system of claim 13 wherein the first side is a front side of the semiconductor substrate, and wherein the second side is a backside of the semiconductor substrate.
